(19) United States
(12) Patent Application Publication
(10) Pub. No.: US 2016/0286152 A1
(43) Pub. Date: Sep. 29, 2016

(54) IMAGING APPARATUS, METHOD OF DRIVING IMAGING APPARATUS, AND IMAGING SYSTEM

(71) Applicant: CANON KABUSHIKI KAISHA, Tokyo (JP)

(72) Inventors: Daisuke Kobayashi, Kawaguchi-shi (JP); Toshiaki Ono, Ebina-shi (JP)

(21) Appl. No.: 15/070,592

(22) Filed: Mar. 15, 2016

(30) Foreign Application Priority Data
Mar. 23, 2015 (JP) 2015-059439

(51) Int. Cl. H04N 5/3745; H03M 1/56; H04N 5/378

(52) U.S. Cl. CPC H04N 5/37455; H04N 5/378; H03M 1/56

(57) ABSTRACT

Provided is a method of driving an imaging apparatus, including: a first step of generating, by at least some of a plurality of comparison circuits, a determination signal that indicates a result of a comparison made between an electric potential of a photoelectric conversion signal and a predetermined electric potential; a second step of setting, based on the determination signal generated by the at least some of the plurality of comparison circuits, an amount of change with time of an electric potential of a reference signal, which is input to at least two of the plurality of comparison circuits; and a third step of performing, by each of the plurality of comparison circuits, analog-to-digital conversion of the photoelectric conversion signal based on a result of a comparison made between the photoelectric conversion signal and the reference signal set in the second step.

### BACKGROUND OF THE INVENTION

1. Field of the Invention

The present invention relates to an imaging apparatus, a method of driving the imaging apparatus, and an imaging system.

2. Description of the Related Art

In Japanese Patent Application Laid-Open No. 2013-9087, there is described a technology of executing analog-to-digital (AD) conversion by changing the rate of change with time of the electric potential of a reference signal (ramp signal) that is input to a comparison circuit, depending on the signal level. The comparison circuit is provided for each column in a pixel unit, and a control signal (select signal) that is used to change the rate of change of the reference signal is transmitted for each column of the pixel unit as well.

The technology described in Japanese Patent Application Laid-Open No. 2013-9087 requires a control signal line for each column of the pixel unit to transmit the control signal for changing the rate of change of the reference signal one column. The number of wiring lines is accordingly large, which complicates the circuit configuration. This is more noticeable when an increase in the number of AD conversion circuits is brought about by an increase in number of pixels.

### SUMMARY OF THE INVENTION

According to one embodiment of the present invention, there is provided a method of driving an imaging apparatus, the imaging apparatus including a plurality of pixels arranged in rows and columns to generate a photoelectric conversion signal, and a plurality of comparison circuits, each provided correspondingly to one of columns of the plurality of pixels, to which the photoelectric conversion signal and a reference signal are to be input, the method including: a first step of generating, by at least some of the plurality of comparison circuits, a determination signal that indicates a result of a comparison made between an electric potential of the photoelectric conversion signal and a predetermined electric potential; a second step of setting, based on the determination signal generated by the at least some of the plurality of comparison circuits, an amount of change with time of an electric potential of a reference signal, which is input to at least two of the plurality of comparison circuits; and a third step of performing, by each of the plurality of comparison circuits, analog-to-digital conversion of the photoelectric conversion signal based on a result of comparison made between the photoelectric conversion signal and the reference signal set in the second step.

Further features of the present invention will become apparent from the following description of exemplary embodiments with reference to the attached drawings.

### BRIEF DESCRIPTION OF THE DRAWINGS

FIG. 1 is a diagram for illustrating a configuration example of an imaging apparatus according to a first embodiment of the present invention.

FIG. 2 is a diagram for illustrating a circuit configuration example of a pixel according to the first embodiment.

FIG. 3 is a diagram for illustrating a configuration example of a comparator according to the first embodiment.

FIG. 4 is a diagram for illustrating AD conversion operation according to the first embodiment.

FIG. 5 is a diagram for illustrating a configuration example of signal processing units according to the first embodiment.

FIG. 6 is a diagram for illustrating a configuration example of signal processing units according to a modification example of the first embodiment.

FIG. 7 is a diagram for illustrating a configuration example of signal processing units according to another modification example of the first embodiment.

FIG. 8 is a diagram for illustrating a configuration example of signal processing units according to still another modification example of the first embodiment.

FIG. 9 is a diagram for illustrating a configuration example of an imaging apparatus according to a second embodiment of the present invention.

FIG. 10 is a diagram for illustrating a configuration example of signal processing units according to the second embodiment.

FIG. 11 is a diagram for illustrating the operation of a digital signal processing unit according to the second embodiment.

FIG. 12 is a diagram for illustrating the operation of a digital signal processing unit according to a modification example of the second embodiment.

FIG. 13 is a diagram for illustrating the operation of a digital signal processing unit according to another modification example of the second embodiment.

FIG. 14 is a diagram for illustrating a configuration example of an imaging apparatus according to a third embodiment of the present invention.

FIG. 15 is a diagram for illustrating a configuration example of an amplifier according to the third embodiment.

FIG. 16 is a diagram for illustrating AD conversion operation according to the third embodiment.

FIG. 17 is a diagram for illustrating a configuration example of a comparator according to a modification example of the third embodiment.

FIG. 18 is a diagram for illustrating a configuration example of an imaging apparatus according to a fourth embodiment of the present invention.

FIG. 19 is a diagram for illustrating a circuit configuration example of a pixel according to the fourth embodiment.

FIG. 20 is a schematic diagram for illustrating a pixel structure according to the fourth embodiment.

FIG. 21 is a diagram for illustrating a configuration example of signal processing units according to the fourth embodiment.

FIG. 22 is a block diagram of an imaging system according to a fifth embodiment of the present invention.

### DESCRIPTION OF THE EMBODIMENTS

Preferred embodiments of the present invention will now be described in detail in accordance with the accompanying drawings. The same components are denoted by the same reference symbols throughout the drawings, and a description on duplicate components may be shortened or omitted. Described below is an example in which a photoelectric converter accumulates electrons in an amount based on the amount of incident light. In the opposite case where the photoelectric converter accumulates holes in an amount based on the amount of incident light, the electric potential in the following description is changed accordingly.

### First Embodiment

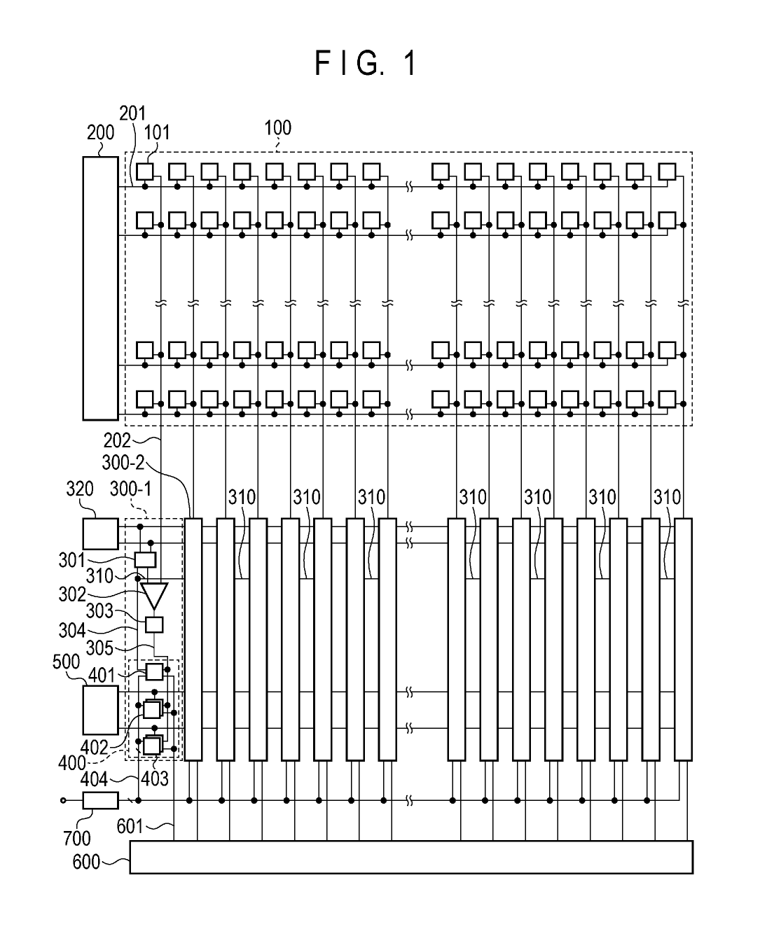

FIG. 1 is a diagram for illustrating a configuration example of an imaging apparatus according to a first embodiment of the present invention. The imaging apparatus includes a pixel array 100, a pixel driving unit 200, a plurality of signal processing units 300, a reference signal source 320, a counter circuit 500, a horizontal scanning unit 600, and a digital signal processing unit 700.

The pixel array 100 has a plurality of pixels 101 arranged in rows and columns. The number of rows of pixels 101 and the number of columns of pixels 100 in the pixel array 100 are given as N and M, respectively. One signal processing unit 300 is provided for each column of the pixels 101 in the pixel array 100, and the pixels 101 that are placed in the same column in the pixel array 100 are connected to one of the signal processing units 300 that is assigned to this pixel column via a pixel output line 202 of the pixel column. In the following description and the drawings, the signal processing unit 300 that corresponds to a particular column of the pixel array 100 is denoted by suffixing 300 with the column number, as in 300-1, 300-2 . . . 300-M. The suffix is omitted when there is no need to specify a column, and the signal processing unit in this case is denoted by 300. Similar notation may be employed for the reference symbols of other components.

The pixel driving unit 200 controls the pixels 101 by outputting a pixel drive signal via pixel driving signal lines 201, which are each provided for one of the rows of the pixel array 100. A plurality of pixels 101 placed in a row that is selected by the pixel driving unit 200 output signals to their respective pixel output lines 202. The output signals are hereinafter referred to as pixel signals.

Each signal processing unit 300 includes at least an analog-to-digital conversion circuit (AD conversion circuit) and a memory group 400, and performs AD conversion on a pixel signal input via the relevant pixel output line 202 to output the converted signal as digital data. The pixel signal converted into digital data is held by the memory group 400.

The horizontal scanning circuit 600 selects a column where a signal is to be output from the memory group 400 by outputting a memory select signal via a memory select signal line 601 to the memory group 400 of the column. The memory group 400 of the column selected by the horizontal scanning circuit 600 transfers pixel signals to the digital signal processing unit 700 via a memory output line 404. The transferred pixel signals are processed by the digital signal processing unit 700, and then output by an output unit (not shown) to an external apparatus outside the imaging apparatus.

These components of the imaging apparatus may be formed on the same semiconductor substrate, or may be divided among a plurality of semiconductor substrates.

A more detailed description is given next on the component that forms the imaging apparatus of FIG. 1.

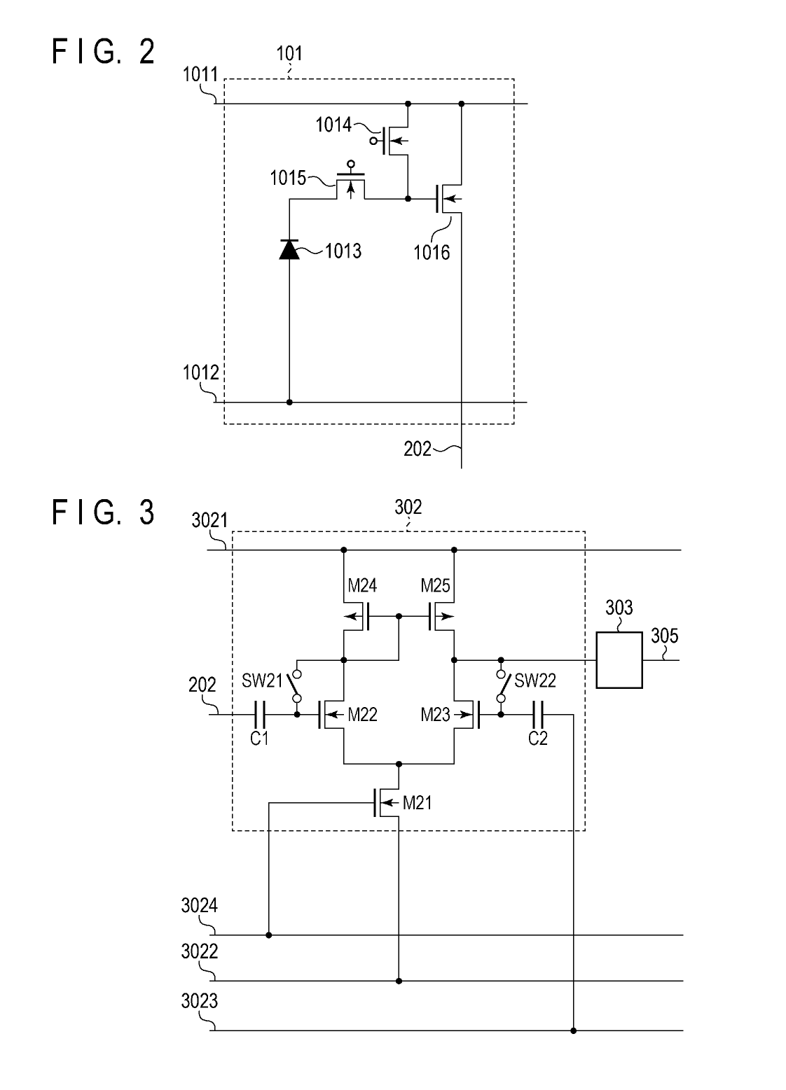

FIG. 2 is a circuit diagram for illustrating a circuit configuration example of each pixel 101. The pixel 101 includes a power supply line 1011, a ground line 1012, a photoelectric converter 1013, a reset switch 1014, a transfer switch 1015, and a source follower transistor 1016. The reset switch 1014, the transfer switch 1015, and the source follower transistor 1016 may be MOS transistors or the like. The reset switch 1014, the transfer switch 1015, and the source follower transistor 1016, which are N-type MOS transistors in the example of FIG. 2, are not limited thereto and can be, for example, P-type MOS transistors.

The power supply line 1011 is wiring through which a power supply electric potential is supplied. The ground line 1012 is wiring through which a ground electric potential is supplied. The photoelectric converter 1013 is a photoelectric conversion element that may be, for example, a photodiode, and generates electric charges in an amount that depends on the amount of incident light to accumulate the electric charges. The reset switch 1014 and the transfer switch 1015 are controlled with a pixel driving signal input from the relevant pixel driving signal line 201.

An anode of the photoelectric converter 1013 is connected to the ground line 1012, and a cathode of the photoelectric converter 1013 is connected to a source of the transfer switch 1015. A drain of the transfer switch 1015 is connected to a gate node of the source follower transistor 1016. A drain of the reset switch 1014 is connected to the power supply line 1011, and a source of the reset switch 1014 is connected to the gate node of the source follower transistor 1016. A drain of the source follower transistor 1016 is connected to the power supply line 1011, and a source of the source follower transistor 1016 is connected to the pixel output line 202.

When the reset switch 1014 and the transfer switch 1015 are switched on, the photoelectric converter 1013 is connected to the power supply line 1011, and the electric potential of the photoelectric converter 1013 is reset. The reset switch 1014 and the transfer switch 1015 are subsequently switched off, thereby breaking the reset state and allowing the photoelectric converter 1013 to accumulate electric charges. The transfer switch 1015 is then turned on, and electric charges are transferred to the gate node of the source follower transistor 1016 via the transfer switch 1015 in an amount that depends on the amount of incident light. At this point, an electric potential that varies depending on the transferred electric charges is output to the pixel output line 202.

The pixel 101 can output two types of signals, a noise signal and a photoelectric conversion signal, as pixel signals. The noise signal is an output signal that precedes the transfer of electric charges from the photoelectric converter 1013 to the gate node of the source follower transistor 1016, and is a signal for obtaining the amount of noise. The photoelectric conversion signal is a signal that is output when electric charges generated by photoelectric conversion are transferred from the photoelectric converter 1013 to the gate node of the source follower transistor 1016, and has an electric potential that varies depending on the amount of incident light. A signal reduced in noise can be obtained by calculating the difference between the photoelectric conversion signal and the noise signal.

The circuit configuration of the pixel 101 that is illustrated in FIG. 2 is an amplification type, which includes the source follower transistor 1016, but a configuration that does not include the source follower transistor 1016 may be employed instead. In other words, the pixel 101 may have a passive circuit configuration, which outputs electric charges generated by photoelectric conversion.

Referring back to FIG. 1, the configuration of each signal processing unit 300 is described in more detail. The signal processing unit 300 includes a reference signal setting unit 301, a comparator 302, a latch circuit 303, and the memory group 400. These circuits give the signal processing unit 300 an AD conversion function and a memory function for storing results of AD conversion. While only one output from the signal processing unit 300 is illustrated in FIG. 1 for the sake of simplification, the signal processing unit 300 is actually configured so that a plurality of bits of the digital data are output in parallel to each other.

The reference signal source 320 outputs a plurality of reference signals different from one another in the rate of change with time of electric potential to the reference signal setting units 301 of the respective columns. A reference signal in this embodiment is a ramp signal having the electric potential that increases or decreases with time in a predetermined slope pattern. Each reference signal setting unit 301 outputs one ramp signal that is selected from among the plurality of ramp signals supplied by the reference signal source 320. The comparator 302 is a comparison circuit configured to compare the voltages of signals input from two input terminals, and output the result to an output terminal. A ramp signal output from the reference signal setting unit 301 is input to one of the two input terminals of the comparator 302, and a pixel signal from the relevant pixel output line 202 is input to the other input terminal of the comparator 302.

An output from the output terminal of the comparator 302 is input to the latch circuit 303. An output of the latch circuit 303 switches from the low level (0) to the high level (1) for a predetermined period in response to a level shift of the output of the comparator 302 from low level to high level. The output of the latch circuit 303 then switches back to the low level. The output of the latch circuit 303 is input to the memory group 400 via a latch output line 305.

The memory group 400 includes a determination signal memory 401 configured to hold determination signals to be used for control of the reference signal setting unit 301, a noise signal memory (hereinafter referred to as N-memory) 402 configured to hold noise signals, and a photoelectric conversion signal memory (hereinafter referred to as S-memory) 403 configured to hold photoelectric conversion signals. The determination signal memory 401 only needs to have a bit count necessary for control of the reference signal setting unit 301. The N-memory 402 and the S-memory 403 each only need to have a bit count appropriate for the resolution of AD conversion. In this embodiment, the bit count of the determination signal memory 401 is 1 bit, the bit count of the N-memory 402 is 8 bits, and the bit count of the S-memory 403 is 10 bits.

A count signal, which indicates a count started at the same time as comparison operation of the comparator 302, is input to the N-memory 402 and the S-memory 403 from the counter circuit 500. The maximum count of the counter circuit 500 is 1,024 in this embodiment. The count signal is input to the N-memory 402 when AD conversion is performed on the noise signal, and is input to the S-memory 403 when AD conversion is performed on the photoelectric conversion signal. Similarly, a latch signal output from the latch circuit 303 is input to one of the two memories depending on which of the noise signal and the photoelectric conversion signal is being converted by AD conversion. The value of the count signal at the time is held as digital data in the N-memory 402 or the S-memory 403 in response to a shift of the latch signal from the high level to the low level.

A determination signal held in the determination signal memory 401 is input to the reference signal setting unit 301 via a determination signal line 304. The reference signal setting unit 301 selects a ramp signal to output based on the input determination signal. The determination signal line 304 of the signal processing unit 300-1 is connected via a common signal line 310 to the adjacent signal processing unit 300-2 as well. The determination signal generated and held by the signal processing unit 300-1 is thus used not only in the signal processing unit 300-1 but also in the reference signal setting unit 301 of the adjacent signal processing unit 300-2. The signal processing unit 300-3 and the signal processing unit 300-4 are similarly connected to each other via another piece of the common signal line 310. In this manner, each signal processing unit in an odd-number column of the pixel array 100 is connected to a signal processing unit that is in an adjacent even-number column via the common signal line 310 in the imaging apparatus of this embodiment.

Pieces of data held in the determination signal memory 401, the N-memory 402, and the S-memory 403 are transferred, when selected by the horizontal scanning unit 600, to the digital signal processing unit 700. The horizontal scanning unit 600 may be a shift register or a decoder. The pieces of data of the memories transferred to the digital signal processing unit 700 undergo predetermined arithmetic processing and then combined to be output to the outside of the imaging apparatus as data of the pixels.

The configuration of the comparator 302 is described in more detail next. FIG. 3 is a diagram for illustrating a configuration example of the comparator 302. The comparator 302 includes transistors M21 to M25, switches SW21 and SW22 for the initialization of the comparator, and input capacitances C1 and C2. The transistors M21, M22, and M23 are N-type MOS transistors and the transistors M24 and M25 are P-type MOS transistors in the example of FIG. 3. However, the transistors M21 to M25 are not limited to this example.

The pixel output line 202 and a ramp signal line 3023 are separately connected to the two input terminals of the comparator 302. The output terminal of the comparator 302 is connected to the latch circuit 303. A power supply line 3021, a ground line 3022, and a drive bias line 3024 are further connected to the comparator 302. The switches SW21 and SW22 are switching elements which may be, for example, MOS transistors, and the switching on/off of the switches SW21 and SW22 is controlled with a control signal (not shown).

The pixel output line 202 is connected to one terminal of the input capacitance C1. The other terminal of the input capacitance C1 is connected to one terminal of the switch SW21 and a gate of the transistor M22. The other terminal of the switch SW21 is connected to a drain of the transistor M22, a drain of the transistor M24, and gates of the transistors M24 and M25. Sources of the transistors M24 and M25 are connected to the power supply line 3021.

The ramp signal line 3023 is connected to one terminal of the input capacitance C2. The other terminal of the input capacitance C2 is connected to one terminal of the switch SW22 and a gate of the transistor M23. The other terminal of the switch SW22 is connected to a drain of the transistor M23, a drain of the transistor M25, and the latch circuit 303.

Sources of the transistors M22 and M23 are connected to a drain of the transistor M21. A gate of the transistor M21 is connected to the drive bias line 3024, and a source of the transistor M21 is connected to the ground line 3022.

The comparator 302 is reset by switching the switches SW21 and SW22 on immediately before AD conversion operation. A drive bias source (not shown) supplies a drive bias to the gate of the transistor M21 via the drive bias line 3024, thereby controlling a drive current of the comparator 302. The pixel signal input from the pixel output line 202 is input to the gate of the transistor M22 via the input capacitance C1. The reference signal input from the ramp signal line 3023 is supplied to the gate of the transistor M23 via the input capacitance C2. The comparator 302 compares the pixel signal input from the pixel output line 202 to the reference signal input from the ramp signal line 3023, and outputs to the latch circuit 303 a signal that indicates the magnitude relation of the electric potentials of these input signals.

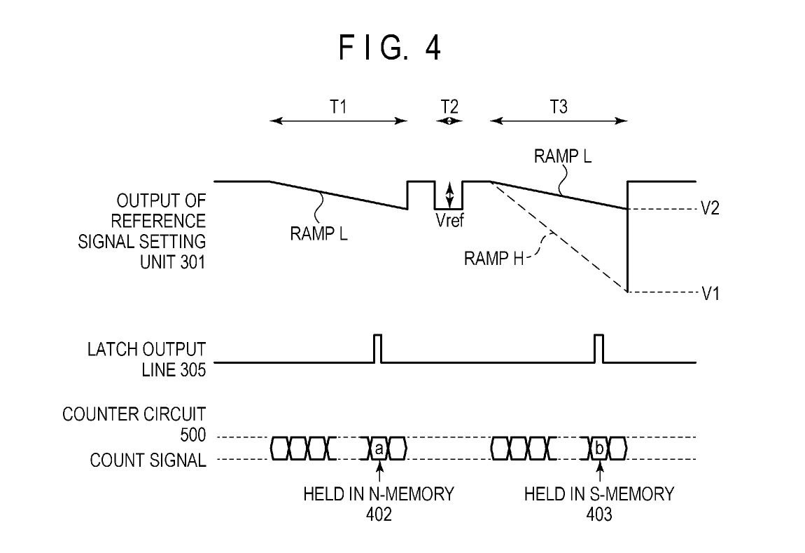

AD conversion operation is described next with reference to FIG. 1 and FIG. 4. The reference signal source 320 in this embodiment supplies a plurality of ramp signals. The reference signal source 320 in this embodiment in this case supplies two types of ramp signals, a ramp H and a ramp L, which differ from each other in slope. The ramp H and the ramp L decrease in electric potential with time in a linear pattern, and the slope of the ramp H is four times larger than the slope of the ramp L.

AD conversion in this embodiment is performed on two signals output from each pixel 101, the noise signal and the photoelectric conversion signal. The reference signal setting unit 301 selects the ramp L as a reference signal for the AD conversion of the noise signal, and selects one of the ramp L and the ramp H as a reference signal for the AD conversion of the photoelectric conversion signal.

The AD conversion of the noise signal is executed in a period T1. Specifically, the noise signal and the ramp L are input to the two input terminals of the comparator 302. When the electric potential of the ramp L drops lower than the electric potential of the noise signal, an electric potential output from the latch circuit 303 via the latch output line 305 to the memory group 400 switches from the low level to the high level for a predetermined period of time, and the output of the latch circuit then switches back to the low level. In response to this, the N-memory 402 holds a count value output from the counter circuit 500. This value is referred to as count value a.

In a period T2, a ramp signal to be used for the AD conversion of the photoelectric conversion signal is selected, and the AD conversion of the photoelectric conversion signal is executed in a period T3. This operation has three steps.

As a first step, the photoelectric conversion signal and a predetermined threshold electric potential Vref are input to the two input terminals of the comparator 302 in the period T2. The comparator 302 compares the electric potential of the photoelectric conversion signal to the threshold electric potential Vref, and outputs a signal that indicates the result of the comparison to the latch circuit 303. The latch circuit 303 outputs a signal that reflects an electric potential change of the signal output by the comparator 302.

The determination signal memory 401 of the memory group 400 holds the output signal of the latch circuit 303. The signal held in the determination signal memory 401 which indicates the result of the comparison between the electric potential of the photoelectric conversion signal and the threshold electric potential Vref is input to the reference signal setting unit 301 via the determination signal line 304. This signal is input also to the reference signal setting unit 301 that is included in the signal processing unit 300 in the adjacent column, via the common signal line 310 connected to the determination signal line 304. For example, a signal indicating the result of the comparison that is held in the determination signal memory 401 of the signal processing unit 300-1 is input to the reference signal setting unit 301 of the signal processing unit 300-1 and the reference signal setting unit 301 of the adjacent signal processing unit 300-2 both.

In a second step subsequent to the first step described above, the reference signal setting unit 301 selects the ramp L when the signal input from the determination signal line 304 indicates that the electric potential of the photoelectric conversion signal is higher than the threshold electric potential Vref. The reference signal setting unit 301 selects the ramp H when the electric potential of the photoelectric conversion signal is lower than the threshold electric potential Vref. This prevents the electric potential of the photoelectric conversion signal from exceeding the dynamic range (acceptable input signal range) of AD conversion.

A preferred value of the threshold electric potential Vref is the lower-limit amplitude value of the dynamic range in the case of AD conversion that uses the ramp L. This sets the reference signal setting unit 301 so as to select the ramp H when using the ramp L in AD conversion makes the electric potential of the photoelectric conversion signal exceed the dynamic range.

When the amplitude of the photoelectric conversion signals of two adjacent columns is around the threshold electric potential Vref, there are cases where the photoelectric conversion signal of one of the columns is within the dynamic range of the ramp L but the photoelectric conversion signal of the other column is outside the dynamic range of the ramp L. If these two columns share the determination signal and the ramp L is selected as a result, the photoelectric conversion signal of the latter column exceeds the dynamic range, which can impair the precision of AD conversion.

This problem can be prevented by setting a redundantly wide dynamic range for AD conversion that uses the ramp L. For example, the threshold electric potential Vref can be set to a value higher than the lower-limit amplitude value of the ramp L to ensure that the AD conversion of the photoelectric conversion signal is kept within the dynamic range when the ramp L is selected. Another way is to control the counter circuit 500 so that the bit count in AD conversion is counted at least one bit higher than a bit count appropriate for the desired resolution of AD conversion.

In a period T3, the AD conversion of the photoelectric conversion signal is executed as a third step with the use of the ramp signal selected in the period T2 described above. When the electric potential of the ramp signal (the ramp L or the ramp H) drops lower than the electric potential of the photoelectric conversion signal, the S-memory 403 holds a count value that is output from the counter circuit 500 at the time. This value is referred to as count value b.

The noise signal and the photoelectric conversion signal are converted by AD conversion in the manner described above, and digital data of the noise signal and digital data of the photoelectric conversion signal are separately held in the N-memory 402 and the S-memory 403. Digital data that indicates the type of a reference signal used in the AD conversion of the photoelectric conversion signal is stored in the determination signal memory 401 as well. These pieces of data are processed in the digital signal processing unit 700.

An example of data processing in the digital signal processing unit 700 is noise reduction of the photoelectric conversion signal which is based on the pieces of data held in the determination signal memory 401, the N-memory 402, and the S-memory 403. The digital signal processing unit 700 first identifies the type of a reference signal used in the AD conversion of the signal in the S-memory 403, based on the data in the determination signal memory 401. The digital signal processing unit 700 then obtains a post-noise reduction count value (b−a) by subtracting the count value a from the count value b in the case where the reference signal used in the AD conversion of the signal in the S-memory 403 is the ramp L. In the case where the reference signal used in the AD conversion of the signal in the S-memory 403 is the ramp H, the digital signal processing unit 700 subtracts the count value a from a value that is the product of multiplying the count value b by a digital gain of 4, which is the ratio of the slope of one ramp signal to the slope of the other ramp signal. The post-noise reduction count value (4×b−a) is obtained as a result.

Other than the noise reduction processing described above, the digital signal processing unit 700 may have a function of attaching an offset to combined data, a function of adjusting gain, and the like.

The signal processing units 300 in this embodiment are aligned with the columns of the pixel array 100. The levels of pixel signals output from the pixels 101 that are adjacent to each other in the pixel array 100 are approximately the same in most cases. Then, the same determination signal is used in the determination signal memories 401 of the adjacent signal processing units 300. A determination signal held in the determination signal memory 401 can therefore be shared between the two adjacent signal processing units 300 via the common signal line 310.

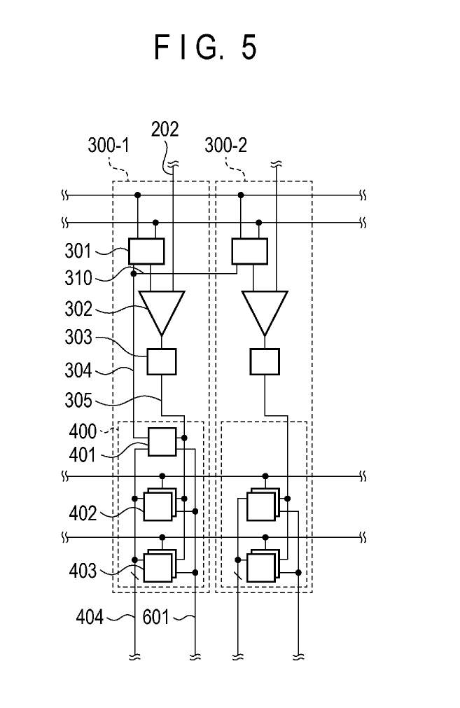

FIG. 5 is a diagram for illustrating a configuration example of the signal processing units 300 according to this embodiment in which the signal processing unit 300-1 and the signal processing unit 300-2 are extracted. In this configuration example, the determination signal memory 401 and determination signal line 304 of the signal processing unit 300-2 are omitted, and the determination signal line 304 of the signal processing unit 300-1 is connected to the reference signal setting unit 301 of the adjacent signal processing unit 300-2 via the common signal line 310. Configuring the signal processing units 300 in this manner enables the adjacent signal processing units 300-1 and 300-2 to share the same determination signal.

The determination signal memory 401 and the determination signal line 304 are omitted from the signal processing unit 300-2 in this embodiment to simplify the circuit. A determination signal is accordingly shared between the adjacent signal processing units 300-1 and 300-2. Further advantages of this configuration are described.

The determination signal line 304 is wiring that connects the reference signal setting unit 301 and the memory group 400 as illustrated in FIG. 1. The determination signal line 304 is therefore often laid near the constituent wiring and elements of the comparator 302, which is disposed between the reference signal setting unit 301 and the memory group 400. In this case, a coupling capacitance is generated between the determination signal line 304 and the constituent wiring and elements of the comparator 302.

When the reference signal setting unit 301 is controlled with the determination signal held in the determination signal memory 401, the electric potential of the determination signal line 304 varies depending on the level of the determination signal. The fluctuations in the electric potential of the determination signal line 304 may affect the electric potential of the constituent wiring and elements of the comparator 302 through the coupling capacitance. This can cause an error in AD conversion executed in the comparator 302. In addition, a through current generated when the electric potential of the determination signal line 304 changes causes power supply noise in some cases.

The AD conversion error and the power supply noise can deteriorate image quality. Image quality deterioration due to these factors is also difficult to correct because how much the image quality is affected varies from one imaging subject to another.

In the configuration of FIG. 5 which is an example of this embodiment, the number of the determination signal lines 304 can be reduced. A wide gap can accordingly be set between each determination signal line 304 and the constituent wiring and elements of the relevant comparator 302, thereby reducing the coupling capacitance. Fewer determination signal lines 304 also mean less effect of power supply noise and, as a result, less image quality deterioration.

Another advantage of the configuration described above, where the determination signal memory 401 and determination signal line 304 of the signal processing unit 300-2 are omitted, is that circuit elements and wiring lines can be reduced in number. The circuit area can be reduced accordingly.

In the configuration described above, where the signal processing unit 300-1 and the signal processing unit 300-2 share a determination signal, the signal processing unit 300-2 does not need to execute the first step of the period T2 in which the electric potential of the photoelectric conversion signal is compared to the threshold electric potential Vref, and thus does not need to put the comparator 302 into operation. In other words, only some of the plurality of comparators 302 generate determination signals in the configuration described above. The comparator 302 of the signal processing unit 300-2 may therefore be powered off in the period T2, which helps to reduce power consumption.

The power supply line 3021 and the ground line 3022 of the signal processing unit 300 in one column are also connected to the signal processing unit 300 in another column, and fluctuations in the electric potentials of the power supply line 3021 and the ground line 3022 can therefore cause cross talk between the signal processing units 300 in the one column and the other column. For example, cross talk may push the comparator 302 off the ideal timing for the output signal level of the comparator 302 to shift, and thus affects the precision of AD conversion. In the configuration described above, where the comparator 302 of the signal processing unit 300-2 does not need to execute comparison operation in the first step, the output electric potential can be kept constant. With fewer comparators 302 fluctuating in output signal level, the electric potential fluctuations of the power supply line 3021 and the ground line 3022 are reduced and cross talk is diminished.

### Modification Examples of the First Embodiment

The present invention is not limited to the circuit configuration and driving method described above, and various modifications can be made. Examples of the modifications are described.

The signal processing unit 300-2, which is not provided with the determination signal memory 401 in FIG. 5, may be provided with the determination signal memory 401. In short, the signal processing unit 300 in every column may be provided with the determination signal memory 401. In this case, the logical sum of pieces of data held in the determination signal memories 401 of the signal processing units 300-1 and 300-2 is calculated and the result of the calculation is output to the determination signal line 304 of the signal processing unit 300-1. In other words, the reference signal used in AD conversion is the ramp H when at least one of the determination signal memory 401 of the signal processing unit 300-1 and the determination signal memory 401 of the signal processing unit 300-2 is at the high level. According to this configuration, the ramp H having a wide dynamic range is used in AD conversion when the level of the photoelectric conversion signal is around the threshold electric potential Vref and the determination signal of one signal processing unit 300 differs from the determination signal of the other signal processing unit 300. This reduces the chance of the AD conversion of the photoelectric conversion signal from exceeding the dynamic range.

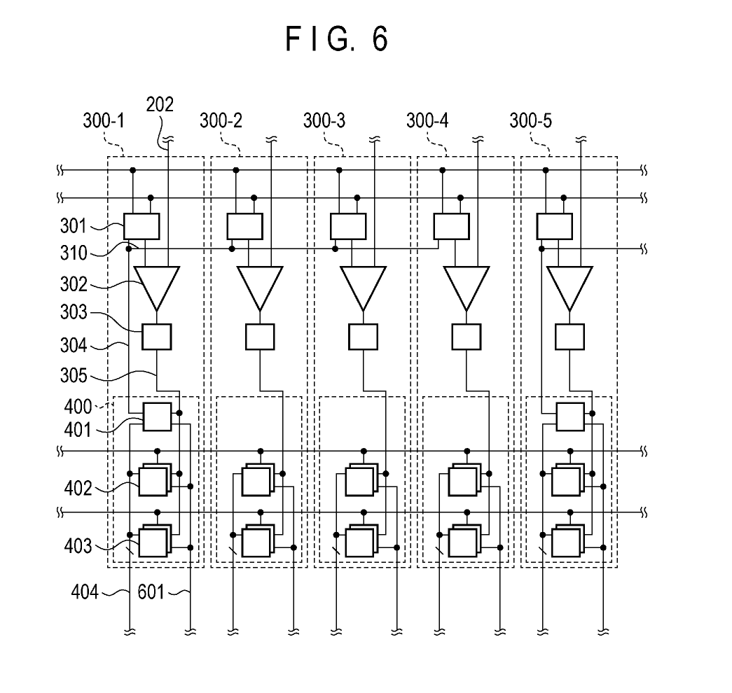

The number of the signal processing units 300 that share a determination signal can be changed at will. FIG. 6 is a diagram for illustrating the configuration of the signal processing units 300 according to a modification example of the first embodiment. In this modification example, the determination signal line 304 of the signal processing unit 300-1 is connected via the common signal line 310 to the reference signal setting unit 301 of each of the adjacent signal processing units 300-2, 300-3, and 300-4. In other words, the signal processing units 300-1, 300-2, 300-3, and 300-4 in four adjacent columns share a determination signal. The number of the signal processing units 300 that share a determination signal can thus be set to an appropriate number suited to the pixel size, the pixel pitch, the pitch between the signal processing units 300, and the like.

In FIG. 6, a determination signal generated in the signal processing unit 300-1 is shared with the adjacent signal processing units 300-2, 300-3, and 300-4 via the determination signal line 304 and the common signal line 310. However, the signal processing unit 300 that generates a determination signal is not limited to the signal processing unit 300-1, and any one of the signal processing units 300-2, 300-3, and 300-4 can generate a determination signal to be shared.

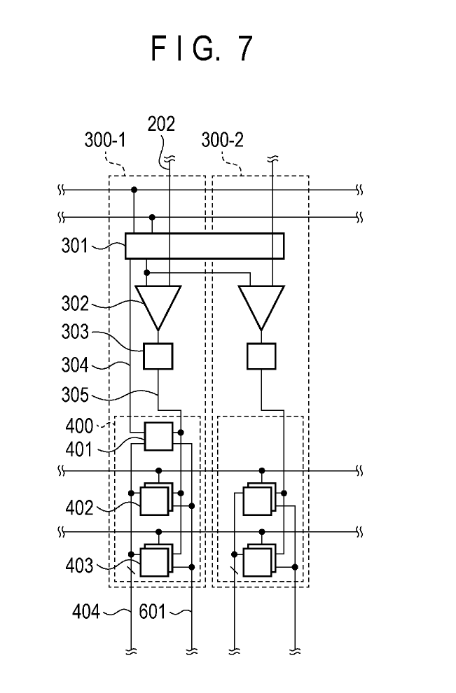

FIG. 7 is a diagram for illustrating the configuration of the signal processing units 300 according to another modification example of the first embodiment. The reference signal setting unit 301 is provided in each of the signal processing units 300-1 and 300-2 in the configuration of FIG. 5. In this modification example, on the other hand, the reference signal setting unit 301 is shared between the signal processing units 300-1 and 300-2. The same effects are obtained with this configuration as well. In other words, providing the reference signal setting unit 301 in every column is not indispensable, and it is sufficient if at least one reference signal setting unit 301 is provided. In this case, a reference signal set by the at least one reference signal setting unit 301 is input to the signal processing units 300 in a plurality of columns.

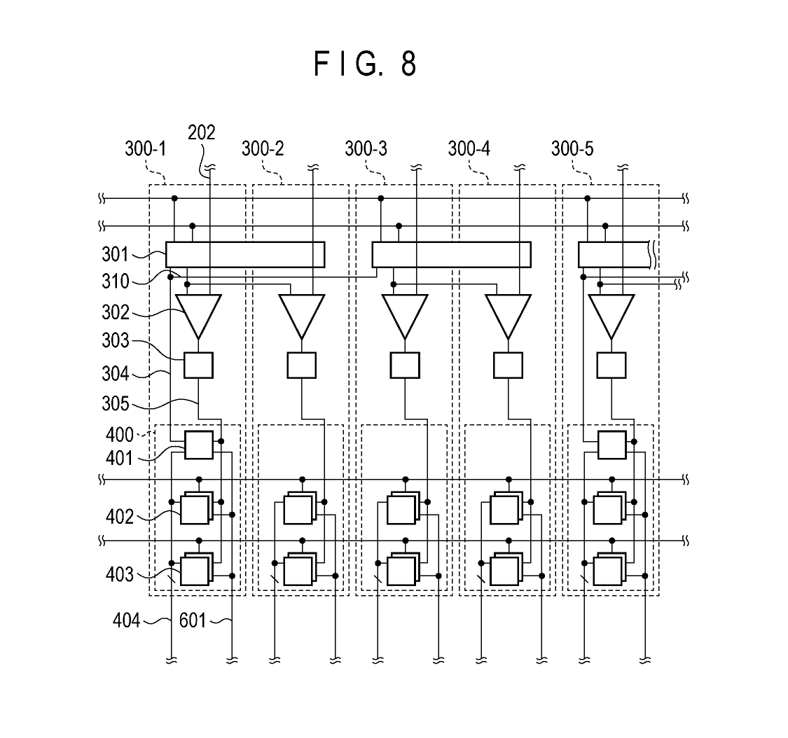

FIG. 8 is a diagram for illustrating the configuration of the signal processing units 300 according to still another modification example of the first embodiment. In this modification example, as in FIG. 7, the reference signal setting unit 301 is shared between the signal processing units 300-1 and 300-2. In addition to this, the determination signal line 304 of the signal processing unit 300-1 is connected via the common signal line 310 to the reference signal setting unit 301 that is shared between the signal processing units 300-3 and 300-4. With this configuration also, the four signal processing units 300-1, 300-2, 300-3, and 300-4 can share a determination signal as in the modification example of FIG. 6, and the same effects are obtained.

### Second Embodiment

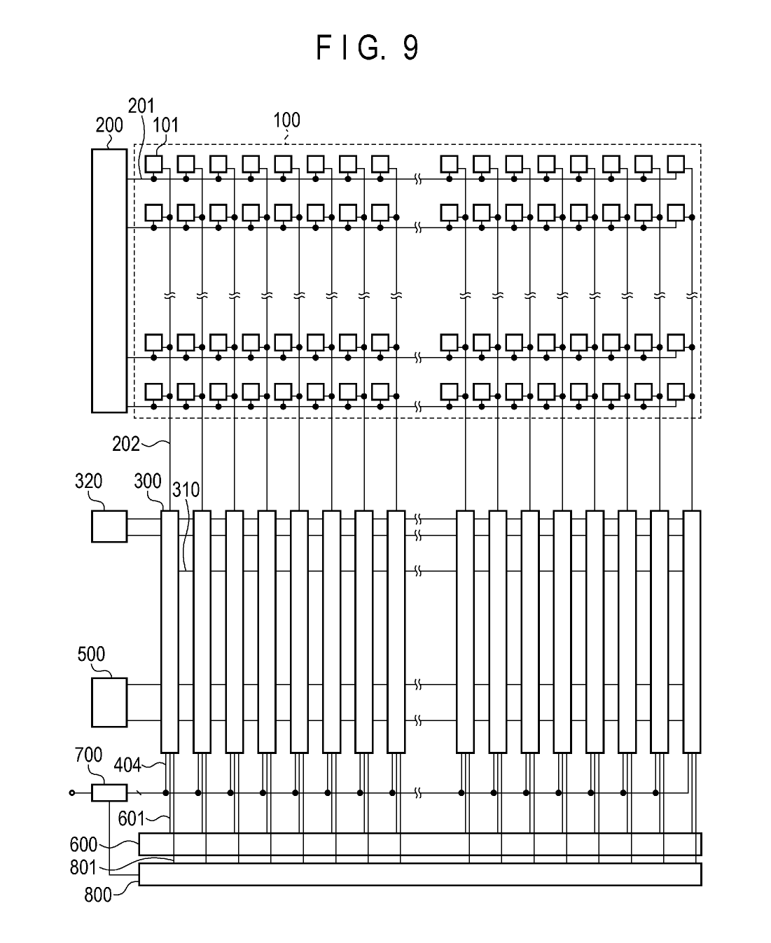

FIG. 9 is a diagram for illustrating a configuration example of an imaging apparatus according to a second embodiment of the present invention. The imaging apparatus of this embodiment includes, in addition to the components of the first embodiment which are illustrated in FIG. 1, a switch control unit 800 configured to control switches for changing columns that share a determination signal, and switch control lines 801 through which control signals are transmitted to the switches.

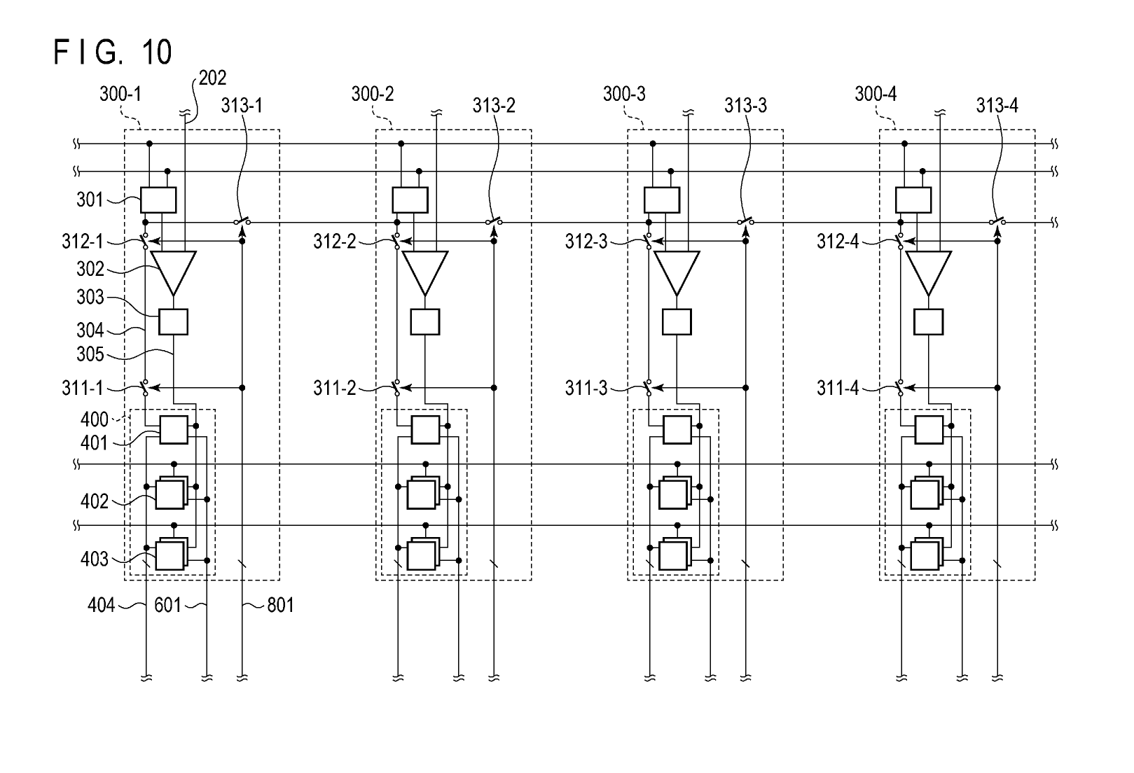

FIG. 10 is a diagram for illustrating a configuration example of the signal processing units 300 according to this embodiment in which the signal processing units 300-1, 300-2, 300-3, and 300-4 are extracted. The signal processing unit 300-1 has switches 311-1, 312-1, and 313-1. The switch 311-1 is connected between the determination signal memory 401 and the determination signal line 304. The switch 312-1 is connected between the determination signal line 304 and the reference signal setting unit 301. The switch 313-1 is connected between the reference signal setting unit 301 of the signal processing unit 300-1 and the reference signal setting unit 301 of the signal processing unit 300-2. The switching on/off of these switches is controlled with control signals that are input from the switch control unit 800 via the switch control lines 801. The same applies to the signal processing units 300-2, 300-3, and 300-4 and other signal processing units 300.

The control of the switches 311, 312, and 313 by the switch control unit 800 is described. The switch control unit 800 is capable of controlling the switches 311, 312, and 313 in each signal processing unit 300 appropriately. Specifically, any number and combination of the signal processing units 300 that share a determination signal can be set. For instance, the imaging apparatus may be set so that all signal processing units 300 share a determination signal, or so that no signal processing units 300 share a determination signal.

An example is discussed in which the switches 311-1, 312-1, and 313-1 are switched on and the switches 311-2, 312-2, and 313-2 are switched off. Similarly, the switches 311-3, 312-3, and 313-3 are switched on and the switches 311-4, 312-4, and 313-4 are switched off. In this circuit configuration, the signal processing units 300-1 and 300-2 share a determination signal, the signal processing units 300-2 and 300-3 do not share a determination signal, and the signal processing units 300-3 and 300-4 share a determination signal. In short, this connection relation is the same as in the first embodiment illustrated in FIG. 1 and FIG. 5. The switch control unit 800 executes the switch control desirably at timing that does not affect AD conversion operation.

The switch control unit 800 can execute control based on an external signal that is transmitted by, for example, serial communication.

The switch control unit 800 may also execute control by referring to data in the determination signal memory 401 which is transferred to the digital signal processing unit 700. This example is described in more detail.

FIG. 11 is a diagram for illustrating operation that is executed when the switches 311, 312, and 313 are controlled based on data that has been transferred from the determination signal memory 401 to the digital signal processing unit 700 via the memory output line 404. The determination signal memories 401 provided in the signal processing units 300 of the respective columns are assigned address numbers 1 to M, which correspond to the column numbers of the signal processing units 300. Each of the determination signal memories 401 store data “0” or data “1”. As described above, data held in the determination signal memory 401 is determined by the magnitude relation between the electric potential of the photoelectric conversion signal and the threshold electric potential Vref.

Data held in each determination signal memory 401 is input to a logical circuit provided in the digital signal processing unit 700. This logical circuit is a coincidence circuit, which outputs “1” when every piece of input data is the same, and otherwise outputs “0”.

A logical circuit illustrated in FIG. 11 has (log₂M) logical outputs. A logical output 1 outputs the result of performing a logical operation by the coincidence circuit described above for every two columns, such as an address 1 and an address 2, an address 3 and an address 4 . . . and an address (M−1) and an address M. The output value takes one of “1” and “0”, which respectively correspond to the switching on and off of the switches 311, 312, and 313. The subsequent logical outputs work in a similar manner, and a logical output 2 outputs the result of performing a logical operation by the described coincidence circuit for every four columns, and a logical output 3 outputs the result of performing a logical operation by the described coincidence circuit for every eight columns. The (log₂M)-th logical output, which is a logical output (log₂M), outputs the result of performing a logical operation for all of the M columns by the coincidence circuit.

A more detailed description is given by taking the addresses 1 to 8 of FIG. 11 as an example. In the example of FIG. 11, data “1” is stored at the addresses 1, 2, 5, 6, 7, and 8, and data “0” is stored at the addresses 3 and 4. As described in the first embodiment, a determination signal having the same data value in one column and another column can be shared with the other column in AD conversion. In the case where a determination signal in one column and a determination signal in another column have different data values, on the other hand, sharing a determination signal between these columns creates a discrepancy in dynamic range between the photoelectric conversion signal and the reference signal, and the columns therefore should not share a determination signal. In FIG. 11, where values stored in the determination signal memory 401 of the first column and the determination signal memory 401 of the second column are both “1”, a determination signal can be shared between the first column and the second column. Similarly, a determination signal can be shared between the third column and the fourth column, and the fifth column to the eighth column can share a determination signal. On the other hand, the second column and the third column, for example, have different data values, and should not share a determination signal.

The output value of each logical output is calculated. The output value of the logical output 1 that is associated with the addresses 1 and 2 is “1”. The output value of the logical output 1 that is associated with the addresses 3 and 4 is also “1”. The output value of the logical output 2 that is associated with the addresses 5, 6, 7, and 8 is “1” as well. The output value of the logical output 2 that is associated with the addresses 1, 2, 3, and 4, on the other hand, is “0”. These output values correspond to the columns' capability/incapability of sharing a determination signal described above. The switch control unit 800 switches on the switches 311, 312, and 313 in the columns that correspond to combinations of addresses where the output values of the logical output 1 to the logical output (log₂M) are “1”. The switch control unit 800 thus executes control in which a determination signal is shared among columns where values stored in the determination signal memories 401 are the same. In the example of FIG. 11, the switches 311, 312, and 313 are switched on in the first column, the third column, the fifth column, the sixth column, and the seventh column.

The switch control unit 800 controls the switches 311, 312, and 313 of the signal processing units 300 by referring to each logical output in this manner. The logical outputs 1, 2 . . . and (log₂M) are input as serial data in this embodiment from the digital signal processing unit 700 to the switch control unit 800.

The number of columns that share a determination signal can be varied depending on the imaging subject or imaging conditions in this embodiment by using the switches 311, 312, and 313 to control how a determination signal is shared in the manner described above. The effects described in the first embodiment are therefore even more improved in this embodiment.

To control the switches in the described processing based on the photoelectric conversion signal on which AD conversion is performed, data in each determination signal memory 401 needs to be transferred before the AD conversion of the photoelectric conversion signal is executed, and the switches 311, 312, and 313 are controlled after the calculation that uses the transferred data is performed. These processing procedures require a waiting time, which means that the processing speed can be increased only to a limited extent. It is therefore preferred to control the switches 311, 312, and 313 by referring to data that is held in the determination signal memory 401 based on the photoelectric conversion signal of a row that precedes a row where the AD conversion of the photoelectric conversion signal is to be executed. This way, time for the processing procedures can be secured and the waiting time is cut short. The first row can be processed properly in this case by treating the first row from the top of an effective pixel region as invalid data, or by setting so that the first row from the top of the effective pixel region does not share the determination signal line 304.

Setting the imaging apparatus for each row by referring to data in the determination signal memory 401 incurs a heavy load on an imaging system or the like. Accordingly, it is also preferred to set the imaging apparatus on a frame-by-frame basis, or only when the imaging apparatus is powered on. Such setting methods are effective when imaging subjects and uses are limited. For instance, in the case where a luminance difference throughout an imaging subject is not large, all columns may share a determination signal to minimize image quality deterioration that is caused by the determination signal lines 304.

### Modification Examples of the Second Embodiment

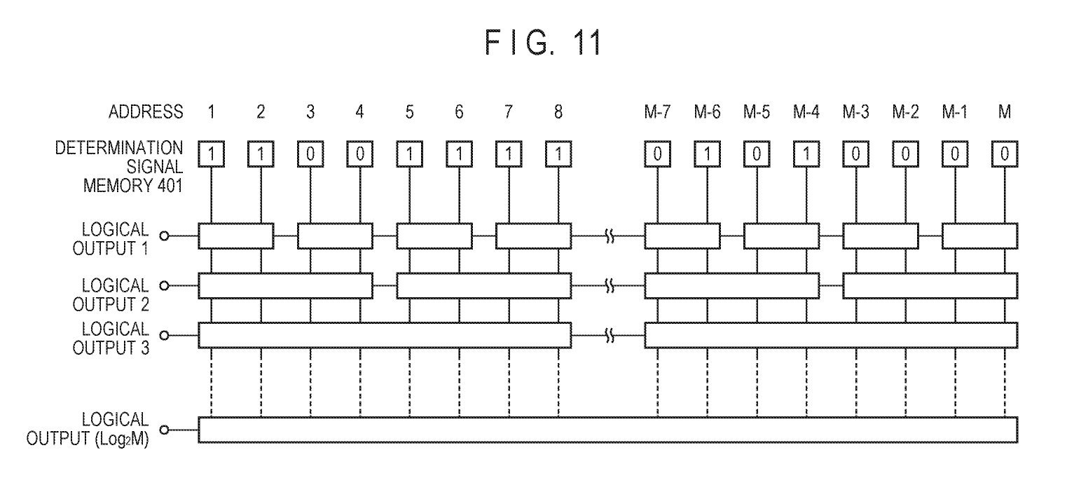

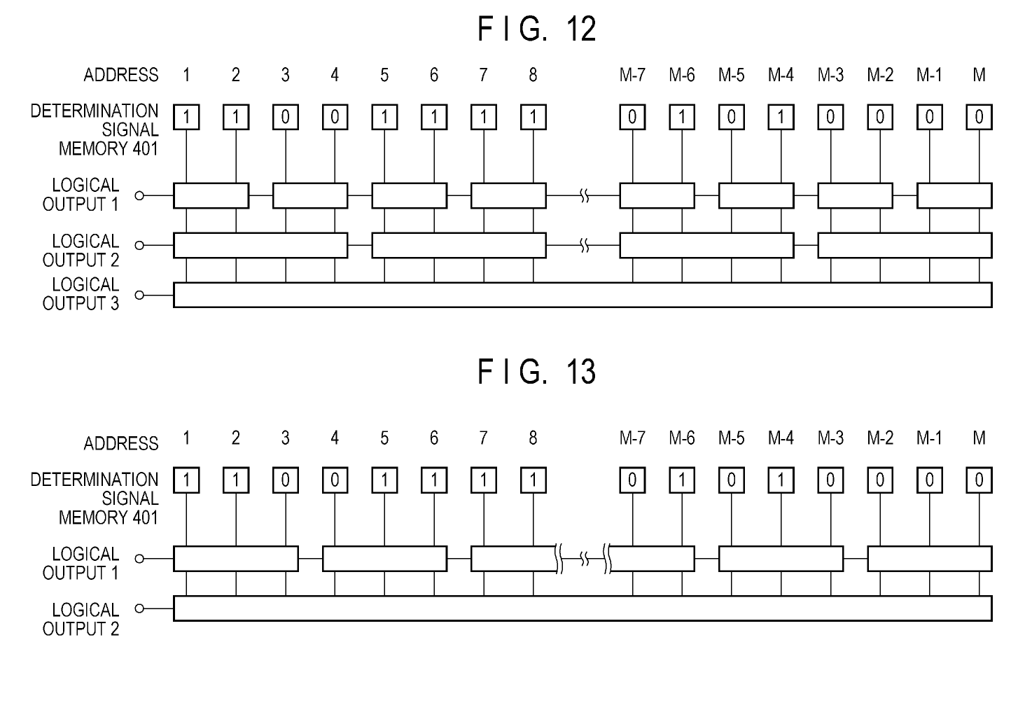

While only (log₂M) stages of logical circuits are disposed in the example of FIG. 11 when the number of columns of the signal processing units 300 is M, the number of logical circuit stages and the like are not limited thereto. For instance, as illustrated in FIG. 12 and FIG. 13, the number of logical circuit stages may be changed suitably, and the number of pieces of data input from the determination signal memories 401 may be varied suitably from one logical circuit to another. FIG. 12 is an example in which the numbers of sharing columns that are associated with the logical outputs 1, 2, and 3 are two columns, four columns, and M columns, respectively. FIG. 13 is an example in which the numbers of sharing columns that are associated with the logical outputs 1 and 2 are three columns and M columns, respectively. In these configurations also, the imaging apparatus can be driven in the same manner as in the example of FIG. 11.

### Third Embodiment

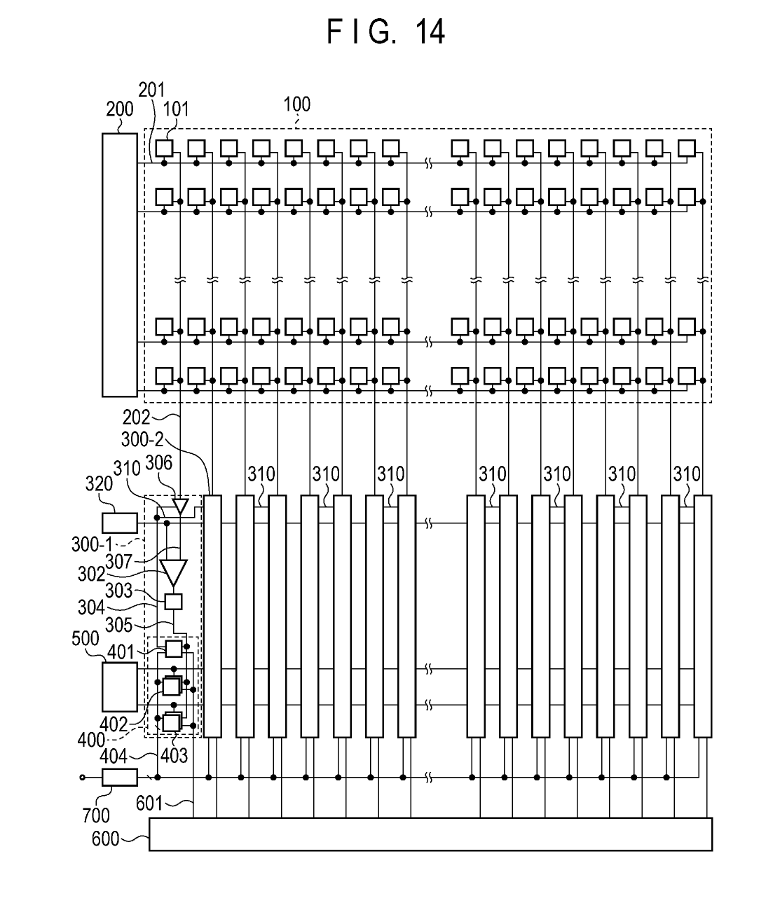

FIG. 14 is a diagram for illustrating a configuration example of an imaging apparatus according to a third embodiment of the present invention. The imaging apparatus of this embodiment includes an amplifier 306 in place of the reference signal setting unit 301 of the first embodiment. An input terminal of the amplifier 306 is connected to the pixel output line 202, and an output terminal of the amplifier 306 is connected to one of the input terminals of the comparator 302 via an amplifier output line 307. A determination signal held in the determination signal memory 401 is input to the amplifier 306 via the determination signal line 304 and is used to change the gain of the amplifier 306. In short, this embodiment is configured so as to switch the gain of the photoelectric conversion signal, instead of switching the slope of the ramp signal which has been described in the first embodiment. In other words, the amplifier 306 of this embodiment functions as an amplification unit. The gain herein can be equal to or less than 1, and “amplification”, “amplifier”, and other similar terms cover cases where the gain is 1 or less.

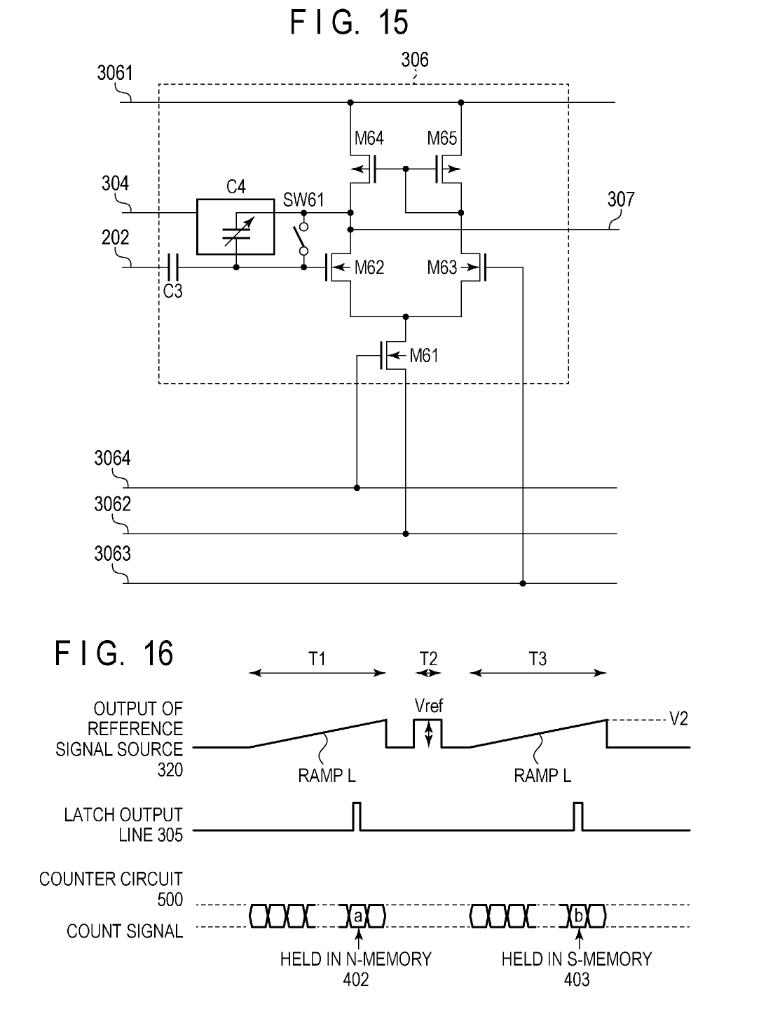

FIG. 15 is a diagram for illustrating a configuration example of the amplifier 306. The amplifier 306 includes transistors M61 to M65, a switch SW61 for initialization, an input capacitance C3, and a gain switching capacitance C4. The transistors M61, M62, and M63 are N-type MOS transistors and the transistors M64 and M65 are P-type MOS transistors in the example of FIG. 15. However, the transistors M61 to M65 are not limited thereto.

The pixel output line 202 is connected to the input terminal of the amplifier 306. A reference signal line 3063 is connected to a reference signal input terminal of the amplifier 306. The output terminal of the amplifier 306 is connected to one of the input terminals of the comparator 302 via the amplifier output line 307. A power supply line 3061, a ground line 3062, and a drive bias line 3064 are further connected to the amplifier 306. The switch SW61 is a switching element that is built from, for example, a MOS transistor, and the switching on/off of the switch SW61 is controlled with a control signal (not shown). The gain switching capacitance C4 is a variable capacitance element that varies in capacitance depending on the determination signal supplied from the determination signal line 304.

The pixel output line 202 is connected to one terminal of the input capacitance C3. The other terminal of the input capacitance C3 is connected to a terminal of the gain switching capacitance C4, a terminal of the switch SW61, and a gate of the transistor M62. The other terminal of the gain switching capacitance C4 and the other terminal of the switch SW61 are connected to a drain of the transistor M62, a drain of the transistor M64, and the amplifier output line 307. A gate of the transistor M64 is connected to a gate of the transistor M65, a drain of the transistor M65, and a drain of the transistor M63. Sources of the transistors M64 and M65 are connected to the power supply line 3061.

The reference signal line 3063 is connected to a gate of the transistor M63. Sources of the transistors M62 and M63 are connected to a drain of the transistor M61. A gate of the transistor M61 is connected to the drive bias line 3064, and a source of the transistor M61 is connected to the ground line 3062.

The amplifier 306 is reset by switching the switch SW61 on immediately before AD conversion operation. A drive bias source (not shown) supplies a drive bias to the gate of the transistor M61 via the drive bias line 3064, thereby controlling a drive current of the amplifier 306.

The amplifier 306 forms an inverting amplifier circuit configured to amplify an electric potential input from the pixel output line 202 by a gain (−C3/C4) and outputs the amplified electric potential to the amplifier output line 307. The gain of the amplifier 306 can therefore be changed by changing the capacitance value of the gain switching capacitance C4.

FIG. 16 is a diagram for illustrating AD conversion operation of this embodiment. FIG. 16 differs from FIG. 4, which is a diagram for illustrating the AD conversion operation of the first embodiment, in that the positive slope and negative slope of the ramp signals used in the periods T1 and T3 are reversed, and in that a ramp signal having the same slope (here, the ramp L) is used in the period T1 and the period T3 both. The positive slope and negative slope of the ramp signals are reversed from the ones in the first embodiment because the amplifier circuit 306, which is an inverting amplifier circuit placed upstream of the comparator 302, inverts the positive sign and negative sign of the electric potential of an input pixel signal.

The operation in the period T1 is substantially the same as in the first embodiment, except that the slope of the ramp signal is reversed, and a description thereof is omitted.

A gain used in the AD conversion of the photoelectric conversion signal is set in the period T2. This operation has two steps.

In a first step, the photoelectric conversion signal and the threshold electric potential Vref are input to the two input terminals of the comparator 302. The comparator 302 compares the photoelectric conversion signal to the threshold electric potential Vref, and outputs a signal that indicates the result of the comparison to the latch circuit 303. The latch circuit 303 outputs a signal that reflects an electric potential change of the signal output by the comparator 302.

The determination signal memory 401 of the memory group 400 holds the output signal of the latch circuit 303. The signal held in the determination signal memory 401 which indicates the result of the comparison between the electric potential of the photoelectric conversion signal and the threshold electric potential Vref is input to the gain switching capacitance C4 of the amplifier 306 via the determination signal line 304. The same signal is input also to the gain switching capacitance C4 of the adjacent column as in the first embodiment. Effects provided by sharing a determination signal are the same as in the first embodiment.

In a second step, the gain switching capacitance C4 changes its capacitance value based on the signal input from the determination signal line 304, to thereby change the gain of the amplifier 306. Specifically, the gain of the amplifier 306 is set to the same value that is used in the AD conversion of the noise signal in the period T1 when the electric potential of the photoelectric conversion signal is lower than the threshold electric potential Vref. When the electric potential of the photoelectric conversion signal is higher than the threshold electric potential Vref, the gain of the amplifier 306 is set to a value ¼ of the value used in the AD conversion of the noise signal in the period T1. This prevents the electric potential of the photoelectric conversion signal from exceeding the dynamic range of the AD conversion as in the case where the ramp signal is given a four times larger slope (as in the case where the ramp H is selected) in the first embodiment.

In the period T3, AD conversion is performed as a third step on the photoelectric conversion signal that has been amplified by the gain selected in the period T2 described above.

The same effects as those in the first embodiment can be obtained in this embodiment by switching the gain of the photoelectric conversion signal, instead of switching the slope of the ramp signal, in the manner described above. There is no need in this embodiment to transmit a plurality of ramp signals having different slopes. Ramp signals can be a cause of noise, cross talk, and the like in some cases. Employing the configuration of this embodiment where the number of ramp signals is reduced is more effective in such cases. As in the second embodiment, the combination of columns that share a determination signal may be controlled with the use of switches.

### Modification Example of the Third Embodiment

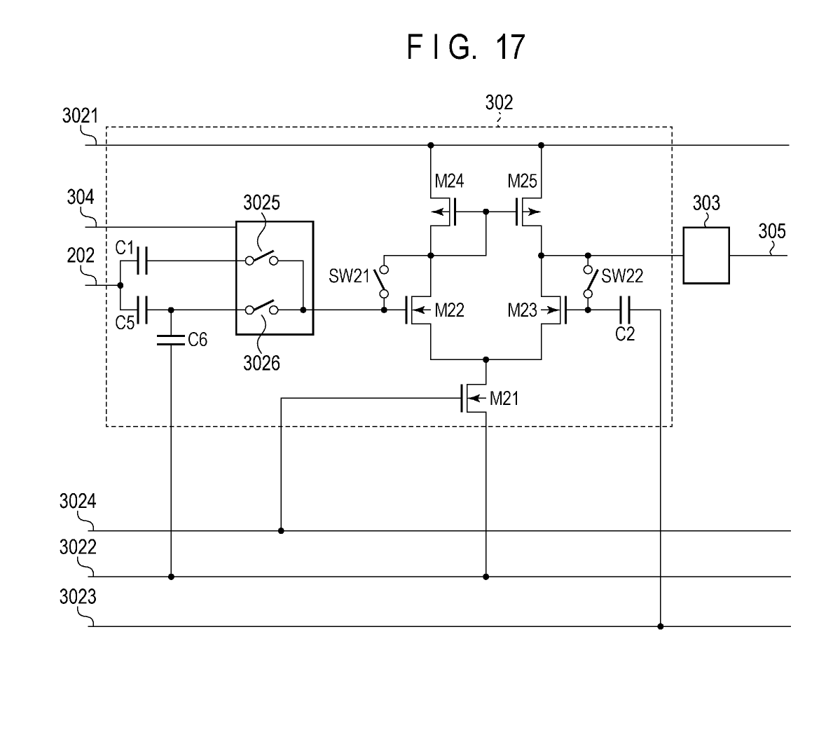

FIG. 17 is a diagram for illustrating a configuration example of a comparator according to a modification example of the third embodiment. In this modification example, the electric potential level of the photoelectric conversion signal is made variable as in the third embodiment, by changing the electric potential of the input photoelectric conversion signal through capacitance division. The comparator 302 of this modification example is obtained by adding an input capacitance C5, a ground capacitance C6, and switches 3025 and 3026 to the comparator of FIG. 3.

The pixel output line 202 is connected to one terminal of the input capacitance C1 and one terminal of the input capacitance C5. The other terminal of the input capacitance C1 is connected to one terminal of the switch 3025. The other terminal of the input capacitance C5 is connected to one terminal of the ground capacitance C6 and one terminal of the switch 3026. The other terminal of the ground capacitance C6 is connected to the ground line 3022. The other terminal of the switch 3025 and the other terminal of the switch 3026 are connected to one terminal of the switch SW21 and the gate of the transistor M22. The switches 3025 and 3026 are controlled with a determination signal input from the determination signal line 304. The rest of the configuration of this modification example is the same as the one in the first embodiment.

When the switch 3025 is switched on and the switch 3026 is switched off, the photoelectric conversion signal input from the pixel output line 202 is input at a gain of 1 to the gate of the transistor M22. When the switch 3025 is switched off and the switch 3026 is switched on, the photoelectric conversion signal input from the pixel output line 202 is input at a gain of (C5/(C5+C6)) to the gate of the transistor M22. The gain is ¼ when the capacitance ratio of the input capacitance C5 and the ground capacitance C6 is 1:3, for example. In other words, the input capacitance C5, the ground capacitance C6, and the switches 3025 and 3026 in this modification example function as an amplification unit as well. The gain of the photoelectric conversion signal can be made variable in this modification example also, through capacitance division. The imaging apparatus can therefore be driven in this modification example in the same manner as in the third embodiment, and the same effects are obtained.

### Fourth Embodiment

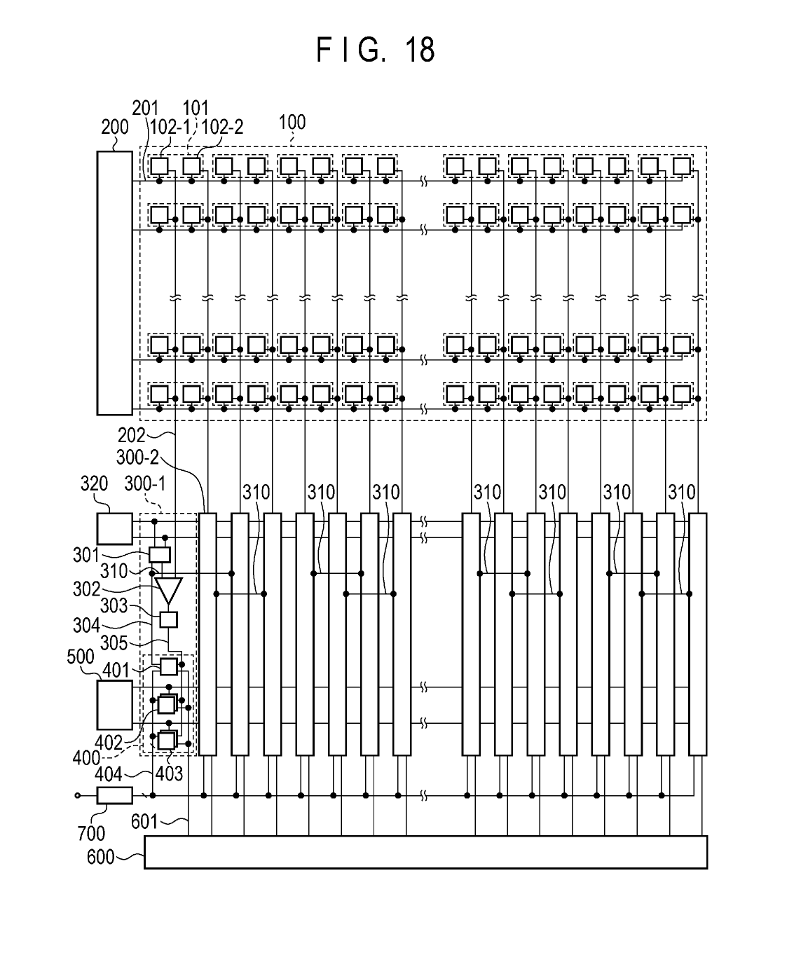

FIG. 18 is a diagram for illustrating a configuration example of an imaging apparatus according to a fourth embodiment of the present invention. This embodiment differs from the first embodiment which is illustrated in FIG. 1 in that each pixel 101 includes two divided pixels, 102-1 and 102-2, and in that a determination signal is shared between every two signal processing units 300 that are one column away from each other.

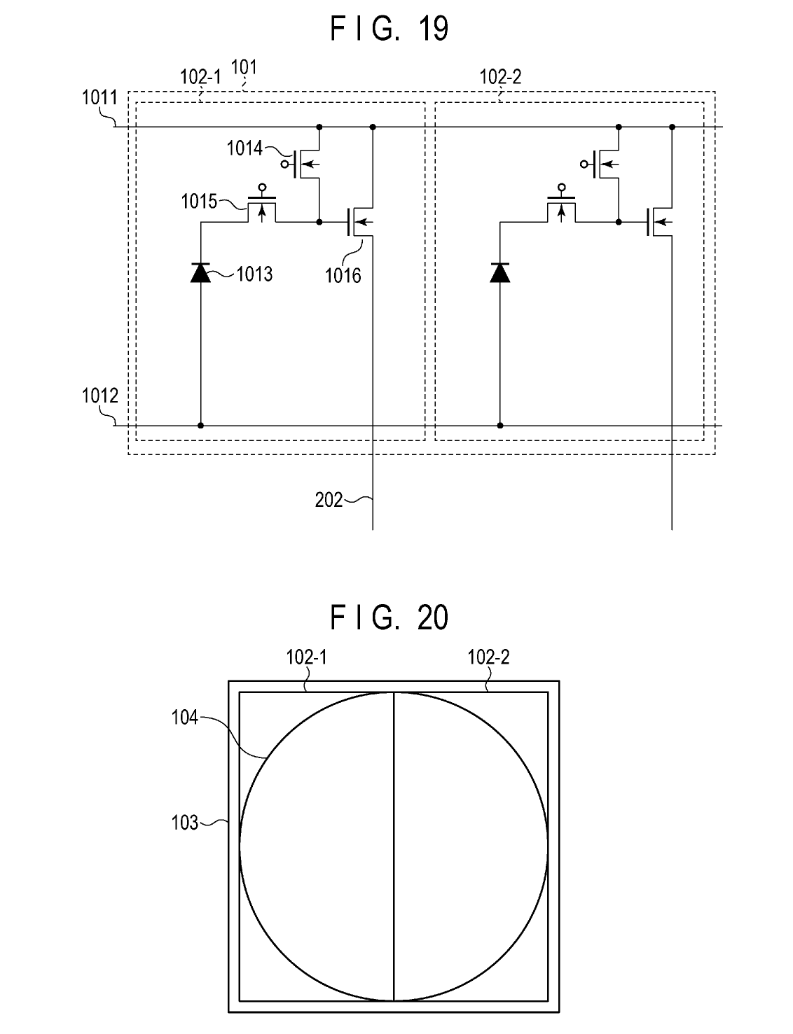

FIG. 19 is a diagram for illustrating a circuit configuration example of each pixel 101 according to the fourth embodiment. The pixel 101 has the divided pixel 102-1, which is disposed on the left side, and the divided pixel 102-2, which is disposed on the right side. The divided pixels 102-1 and 102-2 each have the circuit configuration that is described in the first embodiment with reference to FIG. 2. This means that the divided pixels 102-1 and 102-2 output pixel signals separately from each other.

FIG. 20 is a schematic diagram for illustrating the structure of each pixel 101 according to the fourth embodiment. A color filter 103 and a microlens 104 are formed above the pixel 101. The color filter 103 and the microlens 104 are shared between the two divided pixels 102-1 and 102-2.

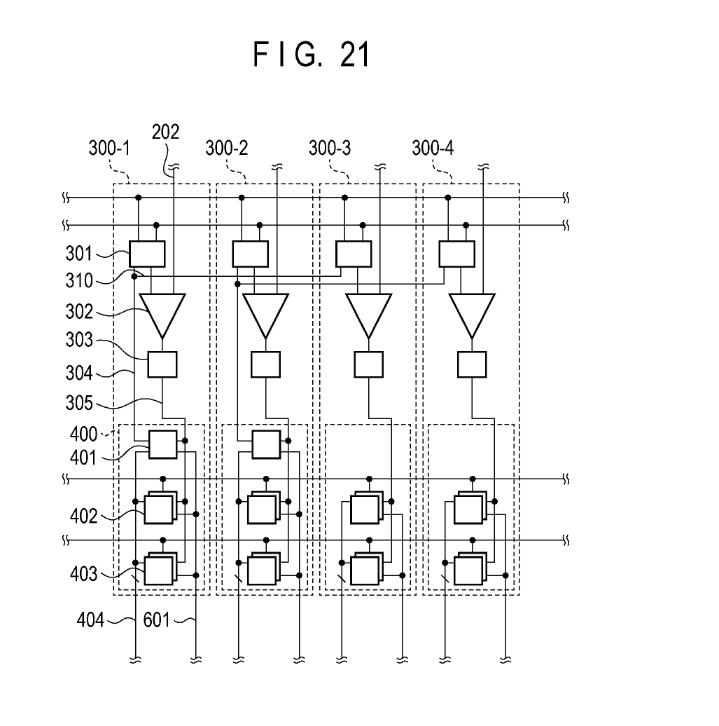

FIG. 21 is a diagram for illustrating a configuration example of the signal processing units 300 according to the fourth embodiment. The determination signal line 304 that is disposed in the signal processing unit 300-1 is connected to the reference signal setting unit 301 of the signal processing unit 300-3 via the common signal line 310. Similarly, the determination signal line 304 that is disposed in the signal processing unit 300-2 is connected to the reference signal setting unit 301 of the signal processing unit 300-4 via another common signal line 310. In other words, a determination signal is shared between every two signal processing units 300 that are one column away from each other.

A level difference caused between a pixel signal of the divided pixel 102-1 and a pixel signal of the divided pixel 102-2 due to a difference in light incident angle can be obtained in each pixel 101 of this embodiment. The imaging apparatus of this embodiment is capable of performing phase difference ranging based on this level difference between the pixel signals. In other words, the difference between the pixel signal output from the divided pixel 102-1 and the pixel signal output from the divided pixel 102-2 can be large, depending on the focal position of an optical system of the imaging apparatus. It is therefore preferred not to share a determination signal between the signal processing unit 300-1 and the signal processing unit 300-2, which correspond to the divided pixels 102-1 and 102-2 in the same pixel, when each pixel 101 is divided as in this embodiment.

On the other hand, there is no large difference between pixel signals of left divided pixels in the adjacent pixels 101 and between pixel signals of right divided pixels in the adjacent pixels 101 in most cases. Accordingly, when each pixel 101 is divided as in this embodiment, a determination signal is to be shared between divided pixels that are included separately by two adjacent pixels 101 and that are in the same position in relation to the microlens. In short, a preferred configuration is that a determination signal is shared between the signal processing units 300 that are one column away from each other, instead of between the signal processing units 300 that are adjacent to each other.

As in the modification examples of the first embodiment, a determination signal may be shared among three or more columns, and the connection relation of each common signal line 310 may be controlled with the use of switches as in the second embodiment. A pixel configuration that employs the method of this embodiment where the determination signal line 304 is shared between columns that are one column away from each other is not limited to pixel configurations that include divided pixels, and may be applied to configurations where a pixel is not divided.

### Fifth Embodiment

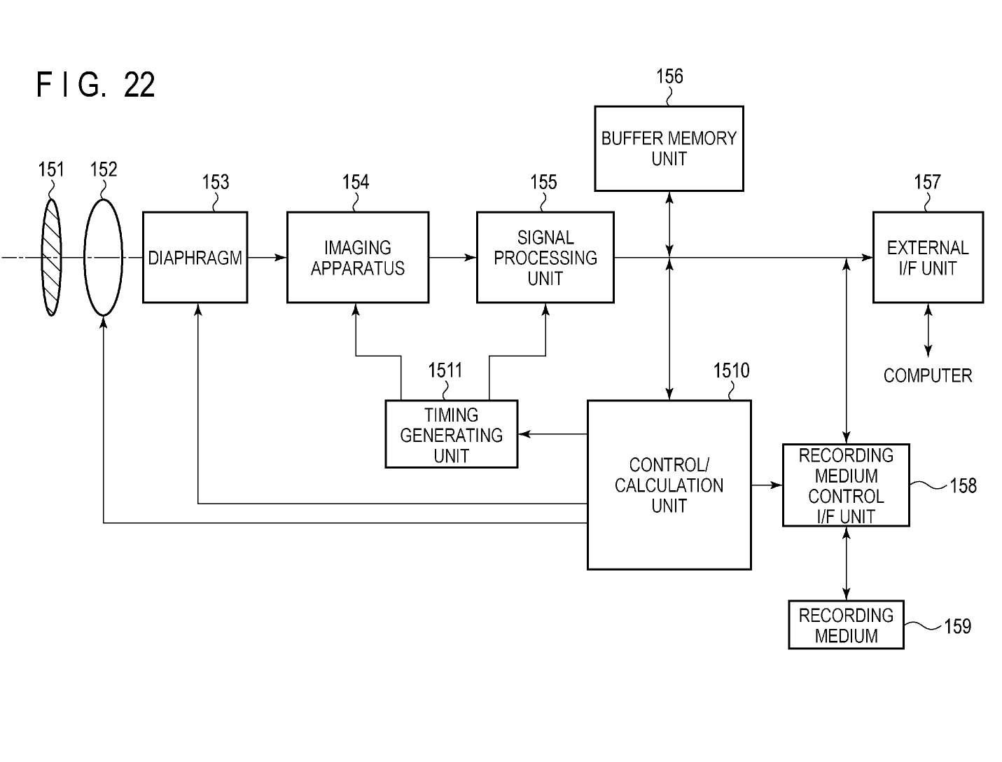

The imaging apparatus of the embodiments described above are applicable to various imaging systems. Examples of the imaging systems include digital still cameras, digital camcorders, and monitoring cameras. FIG. 22 is a block diagram of a digital still camera as an example of an imaging system according to a fifth embodiment of the present invention to which the imaging apparatus of any one of the embodiments described above is applied.

The imaging system illustrated in FIG. 22 as an example includes an imaging apparatus 154, a barrier 151 for the protection of a lens 152, a lens 152, which forms an optical image of an object on the imaging apparatus 154, and a diaphragm 153, which makes the amount of light passed through the lens 152 variable. The lens 152 and the diaphragm 153 form an optical system configured to guide light to the imaging apparatus 154. The imaging apparatus 154 is the imaging apparatus of any one of the embodiments described above. The imaging system of FIG. 22 also includes a signal processing unit 155 configured to process a signal output from the imaging apparatus 154. The signal processing unit 155 generates an image based on a signal output by the imaging apparatus 154. Specifically, the signal processing unit 155 outputs image data after executing various corrections, compression, and other types of processing if necessary. The signal processing unit 155 performs focal point detection as well, with the use of a signal output by the imaging apparatus 154.

The imaging system illustrated in FIG. 22 as an example further includes a buffer memory unit 156 in which image data is stored temporarily, and an external interface unit (external I/F unit) 157 through which communication to and from an external computer or the like is held. Other components of the imaging system include a recording medium 159 such as a semiconductor memory where imaging data is recorded or read, and a recording medium control interface unit (recording medium control I/F unit) 158 with which the recording or reading of the recording medium 159 is executed. The recording medium 159 may be built in the imaging system or may be detachable from the imaging system.

Still other components of the imaging system include a control/calculation unit 1510 configured to perform various calculations and the overall control of the digital still camera, and a timing generating unit 1511 configured to output various timing signals to the imaging apparatus 154 and the signal processing unit 155. The timing signals and other signals may be input from the outside, and it is sufficient if the imaging system includes at least the imaging apparatus 154 and the signal processing unit 155 configured to process a signal output from the imaging apparatus 154.

The imaging system of this embodiment is thus capable of imaging operation by applying the imaging apparatus 154.

According to the first embodiment to the fifth embodiment and the modification examples of the embodiments described above, it is possible to provide an imaging apparatus, a method of controlling the imaging apparatus, and an imaging system capable of transmitting a determination signal for setting AD conversion settings with a simpler configuration.

The imaging system of the fifth embodiment is an example of imaging systems to which a photoelectric conversion apparatus of the present invention can be applied, and imaging systems to which a photoelectric conversion apparatus of the present invention can be applied are not limited to the configuration illustrated in FIG. 22.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. For example, any two or more configurations selected from among the configurations described in the first embodiment to the fifth embodiment and the modification examples of the embodiments may be combined.

This application claims the benefit of Japanese Patent Application No. 2015-059439, filed Mar. 23, 2015, which is hereby incorporated by reference herein in its entirety.

What is claimed is:

1. A method of driving an imaging apparatus, the imaging apparatus comprising a plurality of pixels arranged in rows and columns to generate a photoelectric conversion signal through photoelectric conversion, and a plurality of comparison circuits, each provided correspondingly to one of columns of the plurality of pixels, to which the photoelectric conversion signal and a reference signal are to be input, the method comprising:
a first step of generating, by at least some of the plurality of comparison circuits, a determination signal that indicates a result of a comparison made between an electric potential of the photoelectric conversion signal and a predetermined electric potential;
a second step of setting, based on the determination signal generated by the at least some of the plurality of comparison circuits, an amount of change with time of an electric potential of a reference signal, which is input to at least two of the plurality of comparison circuits; and
a third step of performing, by each of the plurality of comparison circuits, analog-to-digital conversion of the photoelectric conversion signal based on a result of a comparison made between the photoelectric conversion signal and the reference signal set in the second step.

2. The method of driving an imaging apparatus according to claim 1,
wherein the imaging apparatus further comprises a reference signal setting unit configured to set the amount of change with time of the electric potential of the reference signal, a determination signal line through which the determination signal generated by the at least some of the plurality of comparison circuits is to be transmitted, and a switch connected between the determination signal line and the reference signal setting unit, and
wherein the method further comprises setting a connection relation between the determination signal line and the reference signal setting unit by controlling the switch.

3. The method of driving an imaging apparatus according to claim 1, wherein, in the second step, the at least two of the plurality of comparison circuits comprise the at least some of the plurality of comparison circuits, and comparison circuits in columns adjacent to the at least some of the plurality of comparison circuits.

4. The method of driving an imaging apparatus according to claim 2, wherein, in the second step, the at least two of the plurality of comparison circuits comprise the at least some of the plurality of comparison circuits, and comparison circuits in columns adjacent to the at least some of the plurality of comparison circuits.

5. The method of driving an imaging apparatus according to claim 1,
wherein each of the plurality of pixels comprises a plurality of divided pixels that share a microlens, each of the plurality of comparison circuits is provided correspondingly to one of columns of the plurality of divided pixels,
the plurality of pixels includes a first pixel and a second pixel,
the plurality of comparison circuits includes a first comparison circuit and a second comparison circuit,
wherein a relative position between a microlens and one of the divided pixels of the first pixel, and a relative position between a microlens and one of the divided pixels of the second pixel, are same,
the first comparison circuit is provided corresponding to the one of the divided pixels of the first pixel, the second comparison circuit is provided corresponding to the one of the divided pixels of the second pixel.

6. The method of driving an imaging apparatus according to claim 2,
wherein each of the plurality of pixels comprises a plurality of divided pixels that share a microlens,
each of the plurality of comparison circuits is provided correspondingly to one of columns of the plurality of divided pixels,
the plurality of pixels includes a first pixel and a second pixel,
the plurality of comparison circuits includes a first comparison circuit and a second comparison circuit,
wherein a relative position between a microlens and one of the divided pixels of the first pixel, and a relative position between a microlens and one of the divided pixels of the second pixel, are same,
the first comparison circuit is provided corresponding to the one of the divided pixels of the first pixel, the second comparison circuit is provided corresponding to the one of the divided pixels of the second pixel.

7. A method of driving an imaging apparatus, the imaging apparatus comprising a plurality of pixels arranged in rows and columns to generate a photoelectric conversion signal through photoelectric conversion, a plurality of comparison circuits, each provided correspondingly to one column of the plurality of pixels, to which the photoelectric conversion signal and a reference signal are to be input, and a plurality of amplification units provided correspondingly to the plurality of comparison circuits to set, for each of the plurality of comparison circuits, a gain to be used for amplification of an electric potential of the photoelectric conversion signal input to the each of the plurality of comparison circuits, the method comprising:
a first step of generating, by at least some of the plurality of comparison circuits, a determination signal that indicates a result of a comparison between the electric potential of the photoelectric conversion signal that has been amplified by a predetermined gain and a predetermined electric potential;
a second step of setting, by at least two of the plurality of amplification units, a gain to be used for amplification of the electric potential of the photoelectric conversion signal, based on the determination signal generated by the at least some of the plurality of comparison circuits; and
a third step of performing, by each of the plurality of comparison circuits, analog-to-digital conversion of the photoelectric conversion signal based on a result of a comparison made between the reference signal and the photoelectric conversion signal that has been amplified by the gain set in the second step.

8. The method of driving an imaging apparatus according to claim 7,
wherein the imaging apparatus further comprises a determination signal line through which the determination signal generated by the at least some of the plurality of comparison circuits is to be transmitted, and a switch connected between the determination signal line and one of the plurality of amplification units, and
wherein the method further comprises setting a connection relation between the determination signal line and the one of the plurality of amplification units by controlling the switch.

9. The method of driving an imaging apparatus according to claim 7, wherein, in the second step, the at least two of the plurality of comparison circuits comprise the at least some of the plurality of comparison circuits, and comparison circuits in columns adjacent to the at least some of the plurality of comparison circuits.

10. The method of driving an imaging apparatus according to claim 8, wherein, in the second step, the at least two of the plurality of comparison circuits comprise the at least some of the plurality of comparison circuits, and comparison circuits in columns adjacent to the at least some of the plurality of comparison circuits.

11. The method of driving an imaging apparatus according to claim 7,
wherein each of the plurality of pixels comprises a plurality of divided pixels that share a microlens,
each of the plurality of comparison circuits is provided correspondingly to one of columns of the plurality of divided pixels,
the plurality of pixels includes a first pixel and a second pixel,
the plurality of comparison circuits includes a first comparison circuit and a second comparison circuit,
wherein a relative position between a microlens and one of the divided pixels of the first pixel, and a relative position between a microlens and one of the divided pixels of the second pixel, are same,
the first comparison circuit is provided corresponding to the one of the divided pixels of the first pixel, the second comparison circuit is provided corresponding to the one of the divided pixels of the second pixel.

12. The method of driving an imaging apparatus according to claim 8,
wherein each of the plurality of pixels comprises a plurality of divided pixels that share a microlens,
each of the plurality of comparison circuits is provided correspondingly to one of columns of the plurality of divided pixels,
the plurality of pixels includes a first pixel and a second pixel,
the plurality of comparison circuits includes a first comparison circuit and a second comparison circuit,
wherein a relative position between a microlens and one of the divided pixels of the first pixel, and a relative position between a microlens and one of the divided pixels of the second pixel, are same,
the first comparison circuit is provided corresponding to the one of the divided pixels of the first pixel, the second comparison circuit is provided corresponding to the one of the divided pixels of the second pixel.

13. An imaging apparatus, comprising:
a plurality of pixels arranged in rows and columns to generate a photoelectric conversion signal through photoelectric conversion;
a plurality of comparison circuits, each provided correspondingly to one column of the plurality of pixels, to which the photoelectric conversion signal and a reference signal are to be input; and
a reference signal setting unit configured to set an amount of change with time of an electric potential of the reference signal,
wherein at least some of the plurality of comparison circuits are configured to generate a determination signal that indicates a result of a comparison made between an electric potential of the photoelectric conversion signal and a predetermined electric potential,
wherein the reference signal setting unit is configured to set, based on the determination signal generated by the at least some of the plurality of comparison circuits, an amount of change with time of the electric potential of the reference signal, which is input to at least two of the plurality of comparison circuits, and
wherein each of the plurality of comparison circuits is configured to perform analog-to-digital conversion of the photoelectric conversion signal based on a result of a comparison made between the photoelectric conversion signal and the reference signal set by the reference signal setting unit.

14. An imaging apparatus, comprising:
a plurality of pixels arranged in rows and columns to generate a photoelectric conversion signal through photoelectric conversion;
a plurality of comparison circuits, each provided correspondingly to one column of the plurality of pixels, to which the photoelectric conversion signal and a reference signal are to be input; and
a plurality of amplification units provided correspondingly to one of the plurality of comparison circuits to set a gain to be used for amplification of an electric potential of the photoelectric conversion signal input to corresponding one of the plurality of comparison circuits,
wherein at least some of the plurality of comparison circuits are configured to generate a determination signal that indicates a result of a comparison between the electric potential of the photoelectric conversion signal that has been amplified by a predetermined gain and a predetermined electric potential,
wherein at least two of the plurality of amplification units are configured to set a gain to be used for amplification of the electric potential of the photoelectric conversion signal, based on the determination signal generated by the at least some of the plurality of comparison circuits, and
wherein each of the plurality of comparison circuits is configured to perform analog-to-digital conversion of the photoelectric conversion signal based on a result of a comparison made between the reference signal and the photoelectric conversion signal that has been amplified by the gain set by the at least two of the plurality of amplification units.

15. An imaging system, comprising:
an imaging apparatus comprising:
a plurality of pixels arranged in rows and columns to generate a photoelectric conversion signal through photoelectric conversion;
a plurality of comparison circuits, each provided correspondingly to one column of the plurality of pixels, to which the photoelectric conversion signal and a reference signal are to be input; and
a reference signal setting unit configured to set an amount of change with time of an electric potential of the reference signal,
at least some of the plurality of comparison circuits being configured to generate a determination signal that indicates a result of a comparison made between an electric potential of the photoelectric conversion signal and a predetermined electric potential,
the reference signal setting unit being configured to set, based on the determination signal generated by the at least some of the plurality of comparison circuits, an amount of change with time of the electric potential of the reference signal, which is input to at least two of the plurality of comparison circuits,
each of the plurality of comparison circuits being configured to perform analog-to-digital conversion of the photoelectric conversion signal based on a result of a comparison made between the photoelectric conversion signal and the reference signal set by the reference signal setting unit; and
a signal processing unit configured to generate an image based on a signal that is output by the imaging apparatus.

16. An imaging system, comprising:
an imaging apparatus comprising:
a plurality of pixels arranged in rows and columns to generate a photoelectric conversion signal through photoelectric conversion;
a plurality of comparison circuits, each provided correspondingly to one column of the plurality of pixels to which the photoelectric conversion signal and a reference signal are to be input; and
a plurality of amplification units provided correspondingly to one of the plurality of comparison circuits to set a gain to be used for amplification of an electric potential of the photoelectric conversion signal input to the each of the plurality of comparison circuits, at least some of the plurality of comparison circuits being configured to generate a determination signal that indicates a result of a comparison between the electric potential of the photoelectric conversion signal that has been amplified by a predetermined gain and a predetermined electric potential,
at least two of the plurality of amplification units being configured to set a gain to be used for amplification of the electric potential of the photoelectric conversion signal, based on the determination signal generated by the at least some of the plurality of comparison circuits,
each of the plurality of comparison circuits being configured to perform analog-to-digital conversion of the photoelectric conversion signal based on a result of a comparison made between the reference signal and the photoelectric conversion signal that has been amplified by the gain set by the at least two of the plurality of amplification units; and
a signal processing unit configured to generate an image based on a signal that is output by the imaging apparatus.
